(19) United States
(12) Patent Application Publication
(10) Pub. No.: US 2019/0280207 A1
(43) Pub. Date: Sep. 12, 2019

(54) THERMAL TRANSFER FILM FOR PREPARING ORGANIC LIGHT EMITTING DIODE AND METHOD FOR PREPARING THE SAME

(71) Applicant: CHIEN HWA COATING TECHNOLOGY, INC., Hsinchu City (TW)

(72) Inventor: HUNG-HSIN SHIH, TAIPEI CITY (TW)

(21) Appl. No.: 15/972,387

(22) Filed: May 7, 2018

(30) Foreign Application Priority Data
Mar. 9, 2018 (TW) 107108175

(51) Int. Cl. H01L 51/00; C23C 14/24; C23C 14/34; C23C 16/44

(52) U.S. Cl. CPC H01L 51/0013; C23C 14/24; H01L 51/56; C23C 16/44; C23C 14/34

(57) ABSTRACT

A thermal transfer film for preparing Organic Light Emitting Diode (OLED) and a method for preparing the same are revealed. A heat resistant layer and a functional layer are disposed on a base layer respectively by coating. And a transfer layer is arranged over the functional layer. The transfer layer is heated by a thermal print head (TPH) and then is transferred onto a substrate. During the conventional vacuum evaporation used for preparing the OLED, material that reaches the substrate is less than 50%. Compared with the vacuum evaporation, the thermal transfer film and the method for preparing the same solve the problem of low material efficiency.

### BACKGROUND OF THE INVENTION

### Field of the Invention

The present invention relates to a thermal transfer film, especially to a thermal transfer film used for preparing Organic Light Emitting Diode (OLED) and a method for preparing the same.

### Description of Related Art

A semiconductor is a kind of material whose electrical conductivity value falls between that of an insulator and a conductor. The semiconductor plays an important role in technology or for economic development. The most common semiconductor materials include silicon, germanium, gallium arsenide, etc. The silicon is the most common and having widespread commercial applications.

The semiconductor products are widely used in all areas of our lives. For example, Light-Emitting Diode (LED) and Laser Diode (LD) have been applied to illumination, indicator light sources, optical information storage system, laser printer, optical fiber communication and medical field, etc. Other products such as light detectors, solar cells, optical amplifier, transistor, etc. are highly related to our lives in the high tech age. In the era of video communication, the display quality is an important factor to be considered.

Along with the advanced technology and the prevalence of personal computer, internet use and information & communication technology, displays have become an essential means in human-computer interaction. The fast developing display technology is bolstering the flat-panel display industry.

Nowadays a conventional Cathode Ray Tube (CRT) screen is too heavy and relatively bulky for users. Thus the CRT screen has been gradually replaced by a thinner and larger sized Plasma Display Panel (PDP) and much thinner and lighter Liquid Crystal Display (LCD).

Among next generation display technologies, OLED (Organic Light Emitting Diode), also called Organic Electroluminescence, is relatively new. Besides compact volume, the OLED displays have unique advantages such as flexibility, portability, full color and high brightness, power saving, wide viewing angles, no image sticking, etc. Thus the OLED is a powerful new trend of new generation flat panel display and experts in universities and their industrial partners are dedicated to research and development of this new technology.

During operation, a voltage is applied across the OLED so that holes and electrons are injected into the hole injection layer and the electron injection layer, and then passed through the hole transport layer and the electron transport layer respectively. Then the holes and electrons enter the light emitting layer and form excitons that release energy and relax to ground state. The radiative luminescence occurs when the electron transition take places from the excited state of singlet/triplet to the ground state. Only 25% of the energy released (from singlet to the ground state) can be used as light emitted owing to the light emitting material used and spin state characteristics of the electrons while the rest 75% (from triplet to the ground state) is released in the form of phosphorescence or the energy is lost to heat. The frequency of the radiation depends on the band gap of the material used so that the color of the light produced can be varied.

The working principle and operation of OLED are similar to those of LED (light emitting diode). The difference is OLED is made with organic compounds and photons generated inside the organic layers are in the visible range. Thus OLED is a lighting source with higher efficiency.

Moreover, an OLED display requires backlight because it emits visible light. Thus the OLED has optimum visibility and high brightness. The lower the backlight, the less the power consumption. The OLED features on low voltage operation, high power saving efficiency, faster response time, light weight, much thinner thickness, etc. Compared with LCD, OLED has no image retention and works at wide temperature. OLED's response time at low temperature is the same as that at room temperature while the temperature affects LCD. A longer response time is required at low temperature and liquid crystals can even freeze and cause performance problems.

However, certain problems occur during production processes of semiconductor products (such as OLED). Under high vacuum, raw materials are heated and evaporated into atoms or molecules by current, electron beam irradiation, and laser and then to be deposited on a substrate required evenly. A metal mask is required during vacuum evaporation. The method is difficult to scale because that highly accurate positioning of the metal mask is required and larger metal masks are easy to lose accuracy. Thus the substrate used is limited to small scale one, difficult to scale up and unable to be mass produced. The cost of the metal mask is extremely high and a cleaning process is required during production of the metal mask. The positioning of the metal mask should be very accurate.

Furthermore, a lot of LOED materials are wasted during the vacuum evaporation. The vacuum evaporation is simple but inefficient because of 10-40% material utilization after the process.

Thus there is room for improvement and there is a need to provide a novel OLED for solving problems that occurs during conventional vacuum evaporation (such as difficulty in mass production of large-scale products and low material efficiency).

### SUMMARY OF THE INVENTION

Therefore it is a primary object of the present invention to provide a thermal transfer film for preparing Organic Light Emitting Diode (OLED) and a method for preparing the same in which a transfer layer on a functional layer of the thermal transfer film is heated by Thermal Print Head (TPH) and is transferred onto a substrate completely. In the conventional method for preparing the OLED, only less than 50% material reaches the substrate after vacuum evaporation. The problem of low material efficiency can be solved by the present invention.

In order to achieve the above object, a thermal transfer film used for preparing Organic Light Emitting Diode (OLED) according to the present invention includes a base layer, a heat resistant layer disposed on a first surface of the base layer, a functional layer arranged at a second surface of the base layer and having a third surface located over the second surface, and a transfer layer set on a fourth surface of the functional layer.

The base layer is made from a material selected from the group consisting of polyethylene terephthalate (PET), polyimide (PI), poly(ethylene naphthalate) (PEN) and a combination thereof.

The thickness of the base layer is ranging from 2 um to 100 um.

The heat resistant layer is composed of zinc stearate (product name, SPZ-100F), zinc stearyl phosphate (LBT-1830) and cellulose acetate propionate (CAP-504-0.2).

The thickness of the heat resistant layer is from 0.1 um to 3 um.

The functional layer is made from a material selected from the group consisting of silver, aluminum, magnesium, and a combination thereof.

A material for the functional layer is selected from the group consisting of trimethylolpropane triacrylate (TMPTA), polyvinyl butyral (PVB), pentaerythritol tetranitrate (PETN), trinitrotoluene (TNT), acrylic resin, epoxy resin, cellulose resin, PVB resin, polyVinyl chloride (PVC) resin and a combination thereof.

The thickness of the functional layer is ranging from 0.3 um to 10 um.

The transfer layer is made from a material selected from the group consisting of a hole injection material, a hole transport material, a RGB light emitting material, an electron transport material, an electron injection material, a metallic nanomaterial, a carbon nanotube conductive material and a combination thereof.

The transfer layer is mad from a material selected from the group consisting of an arylamine, a polymer mixture of ionomers, a P-dopant, a phenyl arylamine, an organic fluorescent material, an organic phosphorescent material, a thermally-activated delayed fluorescence (TADF) material, a heavy metal complex, an organic polycyclic aromatics, a polycyclic aromatic hydrocarbon (PAH), a blue emitting material, a green emitting material, a red emitting material, a heterocyclic compound, an oxadiazole derivative, a metal chelate, an azole-based derivative, a quinolone derivative, a quinoxaline derivative, an anthrazoline derivative, a phenanthroline derivative, a silole derivative, a fluorobezene derivative, a N-dopant, a metal, an alloy, a metal complex, a metal compound, a metal oxide, an electroluminescent material, an electroactive material, and a combination thereof.

The thickness of the transfer layer is 20 nm˜200 nm.

A method for preparing a thermal transfer film that is used for preparation of OLED according to the present invention includes the following steps. First coat a heat resistant layer solution on a first surface of a base layer to form a heat resistant layer. Then coat a functional layer solution on a second surface of the base layer to form a functional layer and a third surface of the functional layer is located over the second surface. Lastly perform a disposition process by which a transfer layer is arranged at a fourth surface of the functional layer.

Before the step of coating a heat resistant layer solution on a first surface of a base layer to form a heat resistant layer, the method for preparing a thermal transfer film that is used for preparation of OLED further includes the following steps. First take butanone (MEK), toluene, zinc stearate (SPZ-100F), zinc stearyl phosphate (LBT-1830), nano modified clay (C34-M30), a paint additive (KP-341), an anionic surfactant (KC-918), cellulose acetate propionate (CAP-504-0.2) and a dispersant (BYK103) to get a first solution. Then take fatty alcohol polyoxyethylene ether (L75) and butanone (MEK) to form a second solution. Next mix the first solution and the second solution.

The method for preparing a thermal transfer film that is used for preparation of OLED includes the following steps before the step of coating a functional layer solution on a second surface of the base layer to form a functional layer and a third surface of the functional layer being located over the second surface. Take trimethylolpropane triacrylate (TMPTA), polyvinyl butyral (PVB), waterborne resin (Joncry 671), 1-methoxy-2-propanol and butanone (MEK) to form a third solution, use a UV curing agent (Irgacure 369) and butanone (MEK) to form a fourth solution and take a photoinitiator (Irgacure 184) and butanone (MEK) to form a fifth solution. Then mix the third solution, the fourth solution and the fifth solution to form a formulated solution. Lastly use butanone (MEK) as solvent to dilute the formulated solution.

In the step of performing a disposition process by which the transfer layer is set on the fourth surface of the functional layer, the disposition process includes vacuum evaporation, spin coating, slot die coating, inkjet printing, gravure printing, screen printing, chemical vapor deposition (CVD), physical vapor deposition (PVD), and sputtering.

The base layer is made from a material selected from the group consisting of polyethylene terephthalate (PET), Polyimide (PI), poly(ethylene naphthalate) (PEN) and a combination thereof.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a schematic drawing showing structure of an embodiment according to the present invention;

FIG. 2 is a flow chart showing steps for preparing an embodiment according to the present invention;

FIG. 3 is a flow chart showing steps for preparing a heat resistant layer solution of an embodiment according to the present invention;

FIG. 4 is a flow chart showing steps for preparing a functional layer solution of an embodiment according to the present invention;

FIG. 5 is a schematic drawing showing test results of an embodiment made from green emitting material according to the present invention;

FIG. 6 is a schematic drawing showing test results of an embodiment made from blue emitting material according to the present invention;

FIG. 7 is a schematic drawing showing test results of an embodiment made from red emitting material according to the present invention.

### DETAILED DESCRIPTION OF THE PREFERRED EMBODIMENT

In order to learn features and functions of the present invention, please refer to the following embodiments and the related descriptions.

In order to solve problems of the conventional vacuum evaporation used for preparing organic light emitting diode (OLED) (such as difficult scale-up and low material efficiency) that cause high production cost, a thermal transfer film for preparing OLED and a method for preparing the same according to the present invention is provided.

The features, structure and methods of the thermal transfer film for preparing OLED and the method for preparing the same of the present invention are described in detail in the following.

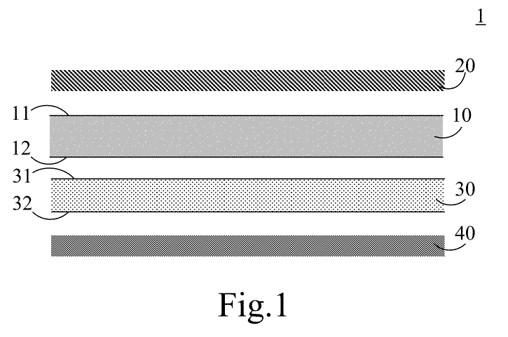

Refer to FIG. 1, a thermal transfer film 1 for preparing Organic Light Emitting Diode (OLED) according to the present invention includes a base layer 10, a heat resistant layer 20 disposed on a first surface 11 of the base layer 10, a functional layer 30 arranged at a second surface 12 of the base layer 10 and having a third surface 31 located over the second surface 12, and a transfer layer 40 set on a fourth surface 32 of the functional layer 30.

The base layer 10 is made from a material selected from the group consisting of polyethylene terephthalate (PET), Polyimide (PI), poly(ethylene naphthalate) (PEN) and a combination thereof. The thickness of the base layer 10 is ranging from 2 um to 100 um.

The heat resistant layer 20 is composed of zinc stearate (SPZ-100F), zinc stearyl phosphate (LBT-1830) and cellulose acetate propionate (CAP-504-0.2). The thickness of the heat resistant layer 20 is ranging from 0.1 um to 3 um.

The functional layer 30 is made from a material selected from the group consisting of silver, aluminum, magnesium, and a combination thereof.

The material for the functional layer 30 can also be selected from the group consisting of trimethylolpropane triacrylate (TMPTA), polyvinyl butyral (PVB), pentaerythritol tetranitrate (PETN), trinitrotoluene (TNT), acrylic resin, epoxy resin, cellulose resin, PVB resin, polyVinyl chloride (PVC) resin and a combination thereof. The thickness of the functional layer 30 is ranging from 0.3 um to 10 um.

The transfer layer 40 is made from a material selected from the group consisting of a hole injection material, a hole transport material, a RGB light emitting material, an electron transport material, an electron injection material, a metallic nanomaterial, a carbon nanotube conductive material and a combination thereof. The thickness of the transfer layer 40 is 20 nm˜200 nm.

The transfer layer 40 can be an anode, a hole injection layer, a hole transport layer, a light emitting layer, an electron transport layer, an electron injection layer, or a cathode.

The anode and the cathode are generally made from conductive materials such as a metal, an alloy, a metal compound, a metal oxide, an electroactive material, a conductive dispersion and a conductive polymer. For example, the materials include gold, platinum, palladium, aluminum, calcium, titanium, titanium nitride (TiN), indium tin oxide (ITO), fluorine-doped tin oxide (FTO), polyaniline, etc.

The hole injection layer is mad from a material selected from the group consisting of an arylamine, a polymer mixture of ionomers (such as PEDOT:PSS), a P-dopant and a combination thereof.

The hole transport layer is made from a material selected from the group consisting of an arylamine, a phenyl arylamine and a combination thereof.

The light emitting layer is made from a material selected from the group consisting of an organic fluorescent material, an organic phosphorescent material, a thermally-activated delayed fluorescence (TADF) material, a heavy metal complex (such as Iridium, Platinum, silver, Osmium, lead, etc.), an organic polycyclic aromatic, a polycyclic aromatic hydrocarbon (PAH), a blue emitting material, a green emitting material, a red emitting material, an electroluminescent material and a combination thereof.

The electron transport layer is made from a material selected from the group consisting of a heterocyclic compound, an oxadiazole derivative, a metal chelate, an azole-based derivative, a quinolone derivative, a quinoxaline derivative, an anthrazoline derivative, a phenanthroline derivative, a silole derivative, a fluorobezene derivative and a combination thereof. The electron injection layer is made from a material selected from the group consisting of a N-dopant, a metal complex and a metal compound (such as an alkali metal compound and an alkaline earth metal compound), and a combination thereof.

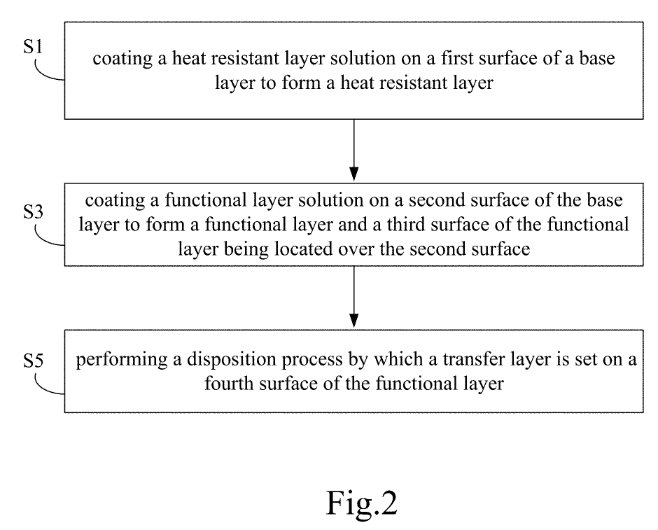

Refer to FIG. 2, a method for preparing a thermal transfer film that is used for preparation of organic light emitting diode (OLED) includes the following steps.

S1: coating a heat resistant layer solution on a first surface of a base layer to form a heat resistant layer;

S3: coating a functional layer solution on a second surface of the base layer to form a functional layer and a third surface of the functional layer being located over the second surface; and

S5: performing a disposition process by which a transfer layer is set on a fourth surface of the functional layer.

In the step S1, the thickness of the heat resistant layer 20 on the first surface 11 of the base layer 10 is 0.1˜3 um.

The thickness of the base layer 10 is ranging from 2 um to 100 um. The base layer 10 is made from a material selected from the group consisting of polyethylene terephthalate (PET), Polyimide (PI), poly(ethylene naphthalate) (PEN) and a combination thereof.

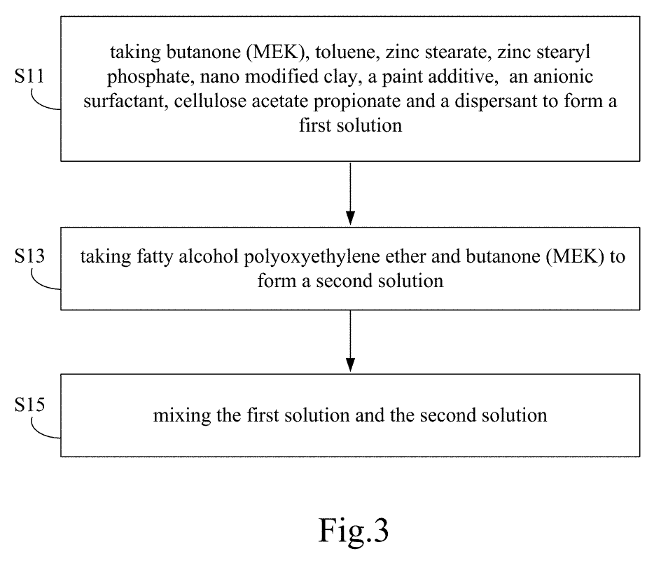

Refer to FIG. 3, a flow chart showing steps for preparing a heat resistant layer solution is revealed. The method for preparing a thermal transfer film that is used for preparation of OLED includes the following steps before the step S1 of coating a heat resistant layer solution on a first surface 11 of a base layer to 10 form a heat resistant layer 20.

S11: taking butanone (MEK), toluene, zinc stearate, zinc stearyl phosphate, nano modified clay, a paint additive, an anionic surfactant, cellulose acetate propionate and a dispersant to form a first solution;

S13: taking fatty alcohol polyoxyethylene ether (AEO) and butanone (MEK) to form a second solution; and

S15: mixing the first solution and the second solution.

As shown in the step S11, take 60.2 g butanone (MEK), 25.8 g toluene, 1.6 g zinc stearate (SPZ-100F), 1 g zinc stearyl phosphate (LBT-1830), 0.5 g nano modified clay (C34-M30), 0.2 g paint additive (KP-341), 0.2 g anionic surfactant (KC-918), 10 g cellulose acetate propionate (CAP-504-0.2) and 0.25 g dispersant (BYK103) to mix and get a first solution. Then stir the first solution for 2 hours for dissolving all of the solutes completely.

Then as shown in the step S13, taking 3 g fatty alcohol polyoxyethylene ether (AEO) (L75) and 3 g butanone (MEK) to form a second solution.

Lastly, as shown in the step S15, the first solution and the second solution are mixed to get the heat resistant layer solution.

Next run the step S1. Use the rotogravure printing machine (Hsing Wei Machine Industry Co., Ltd.) with different mesh count including 135, 150 and 250 to print the heat resistant layer solution on the first surface 11 of the base layer 10. Then the heat resistant layer 20 is formed after the base layer 10 being heated in an oven at 50˜120° C. for 1˜10 min.

Then, as shown in the step S3, coating a functional layer solution on the second surface 12 of the base layer 10 to form the functional layer 30 and the third surface 31 of the functional layer 30 is located over the second surface 12. The thickness of the functional layer 30 is 0.310 um.

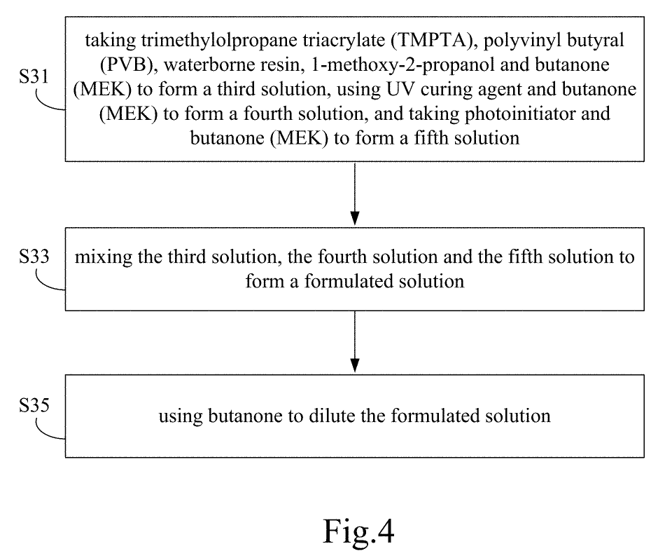

Refer to FIG. 4, a flow chart showing steps for preparing a functional layer solution is revealed. The method for preparing a thermal transfer film that is used for preparation of OLED includes the following steps before the step S3 of coating a functional layer solution on a second surface 12 of the base layer 10 to form a functional layer 30 and a third surface 31 of the functional layer 30 being located over the second surface 12.

S31: taking trimethylolpropane triacrylate (TMPTA), polyvinyl butyral (PVB), waterborne resin, 1-methoxy-2-propanol and butanone (MEK) to form a third solution, using UV curing agent and butanone (MEK) to form a fourth solution, and taking photoinitiator and butanone (MEK) to form a fifth solution;

S33: mixing the third solution, the fourth solution and the fifth solution to form a formulated solution; and

S35: using butanone (MEK) to dilute the formulated solution.

In the step S31, dissolve 14.85 g trimethylolpropane triacrylate (TMPTA), 0.93 g polyvinyl butyral (PVB), 2.78 g waterborne resin (Joncry 671) in 10 g 1-methoxy-2-propanol and 10 g butanone (MEK) to form a third solution. Dissolve 1.25 g UV curing agent (Irgacure 369) in 5 g butanone (MEK) to form a fourth solution. Dissolve 0.19 g photoinitiator (Irgacure 184) in 2.5 g butanone (MEK) to form a fifth solution.

Refer to the step S33, mix 5 g the third solution, 0.81 g the fourth solution and 0.352 g the fifth solution to form a formulated solution.

Lastly, use butanone (MEK) as solvent to dilute the formulated solution to the dissolved solid content required, as shown in the step S35.

Next take the above step S3, use the electric gravure coating machine (K Printing Proofer of RK printcoat instruments) with different mesh count such as 135 or 250 to print the functional layer solution on the second surface 12 of the base layer 10. Then the base layer 10 is heated in an oven at 30˜140° C. for 1˜30 min and later cured by UV radiation so as to form the functional resistant layer 30.

The functional layer 30 is made from a material selected from the group consisting of silver, aluminum, magnesium, and a combination thereof, besides the above formula.

The material for the functional layer 30 can also be selected from the group consisting of trimethylolpropane triacrylate (TMPTA), polyvinyl butyral (PVB), pentaerythritol tetranitrate (PETN), trinitrotoluene (TNT), acrylic resin, epoxy resin, cellulose resin, PVB resin, polyVinyl chloride (PVC) resin and a combination thereof.

Lastly take the step S5, performing a disposition process by which the transfer layer 40 is set on the fourth surface 32 of the functional layer 30. The disposition process includes vacuum evaporation, spin coating, slot die coating, inkjet printing, gravure printing, screen printing, chemical vapor deposition (CVD), physical vapor deposition (PVD), and sputtering.

During the vacuum evaporation, the material for the transfer layer 40 is heated, evaporated, and then deposited on the base layer 10 with the heat resistant layer 20 and the functional layer 30. More specifically, the material is deposited on the fourth surface 32 of the functional layer 30.

In the gravure printing, the material for the transfer layer 40 is dissolved in a solvent such as toluene or chlorobenzene with the dissolved solid content of 0.5˜5%. and then is coated on the base layer 10 arranged with the heat resistant layer 20 and the functional layer 30 by the K Printing Proofer of RK printcoat instruments. The mesh count used is 135 or 250. More specifically, the material is deposited on the fourth surface 32 of the functional layer 30.

The transfer layer 40 is selected from the group consisting of a hole injection material, a hole transport material, a RGB light emitting material, an electron transport material, an electron injection material, a metallic nanomaterial (such as Ag nanowire), a carbon nanotube conductive material and a combination thereof. The thickness of the transfer layer 40 is ranging from 20 nm to 200 nm.

The transfer layer 40 can be an anode, a hole injection layer, a hole transport layer, a light emitting layer, an electron transport layer, an electron injection layer, or a cathode.

The anode and the cathode are generally made from conductive materials such as a metal, an alloy, a metal compound, a metal oxide, an electroactive material, a conductive dispersion and a conductive polymer. For example, the materials include gold, platinum, palladium, aluminum, calcium, titanium, titanium nitride (TiN), indium tin oxide (ITO), fluorine-doped tin oxide (FTO), polyaniline, etc.

The hole injection layer is mad from a material selected from the group consisting of an arylamine, a polymer mixture of ionomers (such as PEDOT:PSS), a P-dopant and a combination thereof.

The hole transport layer is made from a material selected from the group consisting of an arylamine, a phenyl arylamine and a combination thereof.

The light emitting layer is made from a material selected from the group consisting of an organic phosphorescent material, a thermally-activated delayed fluorescence (TADF) material, a heavy metal complex (such as Iridium, Platinum, silver, Osmium, lead, etc.), an organic polycyclic aromatic, a polycyclic aromatic hydrocarbon (PAH), a blue emitting material, a green emitting material, a red emitting material, an electroluminescent material and a combination thereof.

The electron transport layer is made from a material selected from the group consisting of a heterocyclic compound, an oxadiazole derivative, a metal chelate, an azole-based derivative, a quinolone derivative, a quinoxaline derivative, an anthrazoline derivative, a phenanthroline derivative, a silole derivative, a fluorobezene derivative and a combination thereof. The electron injection layer is made from a material selected from the group consisting of a N-dopant, a metal complex and a compound of the same metal (such as an alkali metal compound and an alkaline earth metal compound), and a combination thereof.

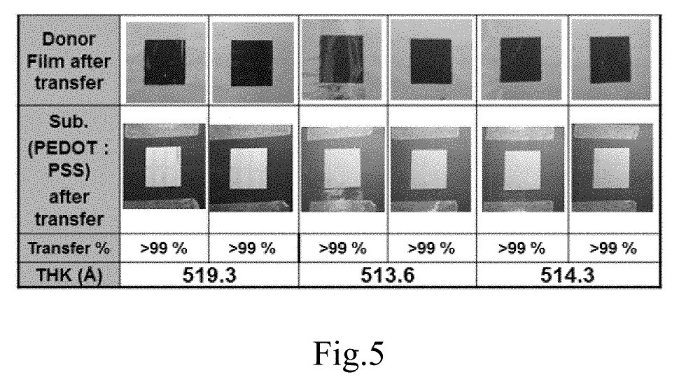

Refer to FIG. 5, an embodiment made from green emitting material is revealed. In this embodiment, CBP:7% Ir(ppy)₃(4,4′-Bis(carbazol-9-yl)biphenyl: Tris(2-phenylpyridine)iridium(III)) is used as the green emitting material and is coated on the functional layer 30 of the thermal transfer film 1 (the donor film) as the transfer film 40 (˜50 nm) by vacuum evaporation. Then the transfer film 40 is heated by the Thermal Print Head (TPH) to be transferred onto a substrate. The substrate is made from PEDOT:PSS (Poly(3,4-ethylenedioxythiophene)-poly(styrenesulfonate)) with the thickness of about ˜30 nm As shown in the figure, the thickness (THK) is 513-519 Å and the transfer ratio is higher than 99% after repeating the experiments.

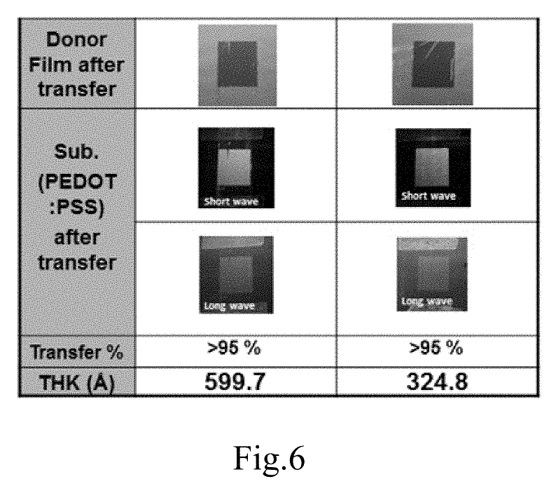

Refer to FIG. 6, an embodiment made from blue emitting material is revealed. In this embodiment, 26DCzPPy+TCTA+FIrPic(2,6-Bis(3-(9H-carbazol-9-yl)phenyl)pyridine+4,4′,4″-Tris(carbazol-9-yl)triphenylamine+bis(3,5-difluoro-2-(2-pyridyl)phenyl-(2-carboxypyridyl)-iridium (III)) is used as the blue emitting material and is coated on the functional layer 30 of the thermal transfer film 1 (the donor film) as the transfer film 40 (˜50 nm) by the wet coating process. Then the transfer film 40 is heated by the Thermal Print Head (TPH) and is transferred onto the substrate. The substrate is made from PEDOT:PSS(Poly(3,4-ethylene-dioxythiophene)-poly(styrenesulfonate)) with the thickness of about 30 nm As shown in the figure, the thickness (THK) is 324.8 Å or 599.7 Å and the transfer ratio is higher than 95% after repeating the experiments.

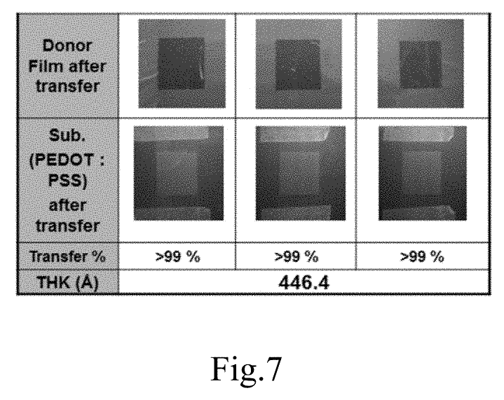

Refer to FIG. 7, an embodiment made from red emitting material is revealed. In this embodiment, TCTA:Ir(PIQ)₂acac(4,4′,4″-Tris(carbazol-9-yl)-triphenylamine:Bis(1-phenylisoquinoline)-(acetylacetonate)iridium(III)) is used as the red emitting material and is coated on the functional layer 30 of the thermal transfer film 1 (the donor film) as the transfer film 40 (about 40 nm) by vacuum evaporation. Then the transfer film 40 is heated by the Thermal Print Head (TPH) and is transferred onto the substrate. The substrate is made from PEDOT:PSS(Poly(3,4-ethylenedioxythiophene)-poly(styrenesulfonate)) with the thickness of about 30 nm As shown in the figure, the thickness (THK) is 446.4 Å and the transfer ratio is higher than 99% after repeating the experiments.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A thermal transfer film used for preparing Organic Light Emitting Diode (OLED) comprising:
a base layer;
a heat resistant layer disposed on a first surface of the base layer;
a functional layer arranged at a second surface of the base layer and having a third surface located over the second surface; and
a transfer layer set on a fourth surface of the functional layer.

2. The device as claimed in claim 1, wherein the base layer is made from a material selected from the group consisting of polyethylene terephthalate (PET), polyimide (PI), poly(ethylene naphthalate) (PEN) and a combination thereof.

3. The device as claimed in claim 1, wherein a thickness of the base layer is ranging from 2 um to 100 um.

4. The device as claimed in claim 1, wherein the heat resistant layer is composed of zinc stearate, zinc stearyl phosphate and cellulose acetate propionate.

5. The device as claimed in claim 1, wherein a thickness of the heat resistant layer is ranging from 0.1 um to 3 um.

6. The device as claimed in claim 1, wherein the functional layer is made from a material selected from the group consisting of silver, aluminum, magnesium, and a combination thereof.

7. The device as claimed in claim 1, wherein a material for the functional layer can also be selected from the group consisting of trimethylolpropane triacrylate (TMPTA), polyvinyl butyral (PVB), pentaerythritol tetranitrate (PETN), trinitrotoluene (TNT), acrylic resin, epoxy resin, cellulose resin, PVB resin, polyVinyl chloride (PVC) resin and a combination thereof.

8. The device as claimed in claim 1, wherein a thickness of the functional layer is ranging from 0.3 um to 10 um.

9. The device as claimed in claim 1, wherein the transfer layer is made from a material selected from the group consisting of a hole injection material, a hole transport material, a RGB light emitting material, an electron transport material, an electron injection material, a metallic nanomaterial, a carbon nanotube conductive material and a combination thereof.

10. The device as claimed in claim 1, wherein the transfer layer is mad from a material selected from the group consisting of an arylamine, a polymer mixture of ionomers (such as PEDOT:PSS), a P-dopant, a phenyl arylamine, an organic fluorescent material, an organic phosphorescent material, a thermally-activated delayed fluorescence (TADF) material, a heavy metal complex, an organic polycyclic aromatic, a polycyclic aromatic hydrocarbon (PAH), a blue emitting material, a green emitting material, a red emitting material, a heterocyclic compound, an oxadiazole derivative, a metal chelate, an azole-based derivative, a quinolone derivative, a quinoxaline derivative, an anthrazoline derivative, a phenanthroline derivative, a silole derivative, a fluorobezene derivative, a N-dopant, a metal, an alloy, a metal complex, a metal compound, a metal oxide, an electroluminescent material, an electroactive material, and a combination thereof.

11. The device as claimed in claim 1, wherein a thickness of the transfer layer is 20 nm˜200 nm.

12. A method for preparing a thermal transfer film that is used for preparation of OLED comprising the steps of:
coating a heat resistant layer solution on a first surface of a base layer to form a heat resistant layer;
coating a functional layer solution on a second surface of the base layer to form a functional layer and a third surface of the functional layer being located over the second surface; and
performing a disposition process by which a transfer layer is arranged at a fourth surface of the functional layer.

13. The method as claimed in claim 12, wherein before the step of coating a heat resistant layer solution on a first surface of a base layer to form a heat resistant layer, the method for preparing a thermal transfer film that is used for preparation of OLED further comprising the steps of:
taking butanone (MEK), toluene, zinc stearate, zinc stearyl phosphate, nano modified clay, a paint additive, an anionic surfactant, cellulose acetate propionate and a dispersant to get a first solution;
taking fatty alcohol polyoxyethylene ether and butanone (MEK) to form a second solution; and
mixing the first solution and the second solution.

14. The method as claimed in claim 12, wherein before the step of coating a functional layer solution on a second surface of the base layer to form a functional layer and a third surface of the functional layer being located over the second surface, the method for preparing a thermal transfer film that is used for preparation of OLED further comprising the steps of:
taking trimethylolpropane triacrylate (TMPTA), polyvinyl butyral (PVB), waterborne resin, 1-methoxy-2-propanol and butanone (MEK) to form a third solution; taking a UV curing agent and butanone (MEK) to form a fourth solution; and taking a photoinitiator and butanone (MEK) to form a fifth solution;
mixing the third solution, the fourth solution and the fifth solution to form a formulated solution; and
using butanone (MEK) as solvent to dilute the formulated solution.

15. The method as claimed in claim 12, wherein in the step of performing a disposition process by which the transfer layer is set on the fourth surface of the functional layer, the disposition process is selected from the group consisting of vacuum evaporation, spin coating, slot die coating, inkjet printing, gravure printing, screen printing, chemical vapor deposition (CVD), physical vapor deposition (PVD), and sputtering.

16. The method as claimed in claim 12, wherein the base layer is made from a material selected from the group consisting of polyethylene terephthalate (PET), Polyimide (PI), poly(ethylene naphthalate) (PEN) and a combination thereof.
